(19) United States
(12) Patent Application Publication
(10) Pub. No.: US 2010/0163953 A1
(43) Pub. Date: Jul. 1, 2010

(54) SEMICONDUCTOR DEVICE AND METHOD OF MANUFACTURING THE SAME

(76) Inventor: Tae Woong Jeong, Chungbuk (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/638,077

(22) Filed: Dec. 15, 2009

(30) Foreign Application Priority Data
Dec. 31, 2008 (KR) 10-2008-0138890

(51) Int. Cl. H01L 29/788; H01L 21/28

(52) U.S. Cl. 257/315; 438/594; 257/E29.3; 257/E21.209

(57) ABSTRACT

Disclosed are a semiconductor device and a method of manufacturing the same. The semiconductor device includes a first polysilicon pattern formed on a semiconductor substrate, a second polysilicon pattern formed at a lateral side of the first polysilicon pattern such that the second polysilicon pattern extends to a height higher than the first polysilicon pattern, a third polysilicon pattern formed in a region restricted by a top surface of the first polysilicon pattern and a lateral side of the second polysilicon pattern, and a contact electrically connected with the second polysilicon pattern and the third polysilicon pattern.

### CROSS-REFERENCE TO RELATED APPLICATION

This application claims the benefit under 35 U.S.C. §119 of Korean Patent Application No. 10-2008-0138890, filed Dec. 31, 2008, which is hereby incorporated by reference in its entirety.

### BACKGROUND

Among semiconductor devices, an electrically erasable programmable read-only memory (EEPROM)-type flash memory device includes a floating gate and a control gate to apply a high voltage to the floating gate through capacitive coupling.

In order to program the EEPROM-type flash memory device, after applying a voltage to the control gate, a voltage is applied to the floating gate in proportion to a coupling rate of the control gate to the floating gate.

In order to erase data from the EEPROM-type flash memory device, charged electrons are emitted from the floating gate by generating a high voltage, so that a threshold voltage of a cell transistor is lowered.

In other words, a voltage is applied to the control gate in proportion to a coupling rate between the control gate and the floating gate, thereby performing program and erase operations.

However, a conventional cell structure has a limitation in improving the coupling rate by using only capacitance corresponding to the area between the control gate and the floating gate facing each other. For this reason, a high voltage is required for the control gate due to the drop of the coupling rate, so that power efficiency may be degraded. Recently, as rapid progress is made in high integration, a cell size is reduced. Accordingly, research and studies have been carried out to maintain a uniform structure between cells.

### BRIEF SUMMARY

Semiconductor devices and methods for manufacturing the same are provided that can be utilized for memory devices. According to one embodiment, a semiconductor device is provided that includes a first polysilicon pattern formed on a semiconductor substrate; a second polysilicon pattern formed at a lateral side of the first polysilicon pattern, wherein the second polysilicon pattern has a height higher than that of the first polysilicon pattern; a third polysilicon pattern formed in a region restricted by a top surface of the first polysilicon pattern and a lateral side of the second polysilicon pattern; and a contact electrically connected with the second polysilicon pattern and the third polysilicon pattern.

According to another embodiment, a method of manufacturing a semiconductor device is provided that includes forming a second polysilicon pattern having a form of a spacer while making contact with lateral sides of a first oxide layer pattern, a first polysilicon pattern, a second oxide layer pattern, and a first nitride layer pattern that are stacked on a semiconductor substrate; removing the first nitride layer pattern between the second polysilicon pattern at the lateral sides of the stack; forming a pair of hard mask patterns having the form of a spacer in an interior region between the second polysilicon pattern, in which the first nitride layer pattern is removed, wherein the hard mask patterns are on a top surface of the first polysilicon pattern and interior sidewalls of the second polysilicon pattern; forming first polysilicon floating gate patterns adjacent to each other by etching the first polysilicon pattern using the hard mask patterns such that the semiconductor substrate is exposed at a central portion of the first polysilicon pattern; gap-filling a space between the first polysilicon floating gate patterns; forming a third polysilicon pattern in a region restricted by a top surface of the first polysilicon floating gate patterns and a lateral side of the second polysilicon pattern; and forming a contact electrically connected with the second polysilicon pattern and the third polysilicon pattern such that the second polysilicon pattern and the third polysilicon pattern are shorted together.

### BRIEF DESCRIPTION OF THE DRAWINGS

FIGS. 1 to 13 are cross-sectional views showing a method of manufacturing a semiconductor device according to an embodiment.

### DETAILED DESCRIPTION

Hereinafter, embodiments of a semiconductor device and a method of manufacturing the same will be described with reference to accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

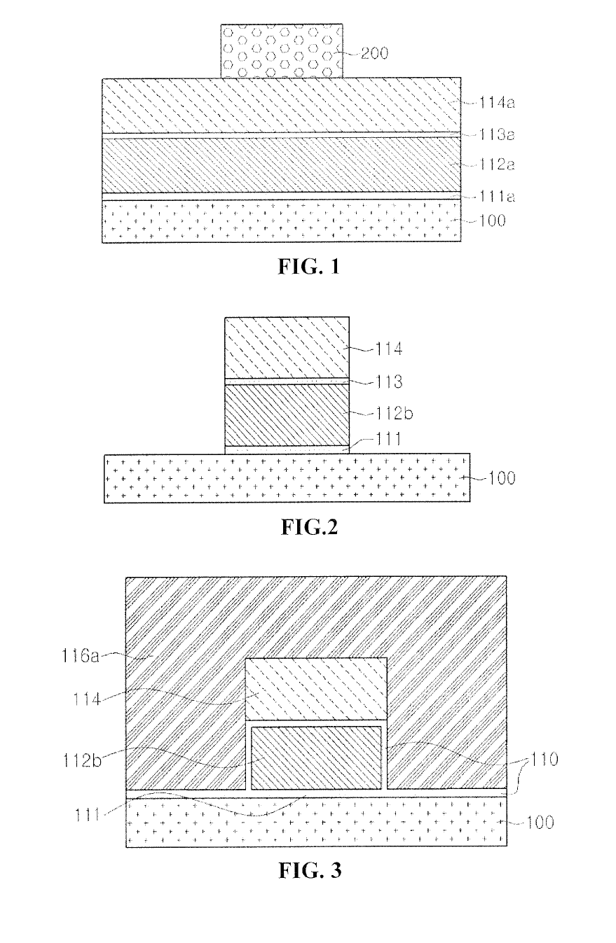

FIGS. 1 to 13 are cross-sectional views showing a method of manufacturing a semiconductor device according to an embodiment.

An isolation layer (not shown) can be formed on a semiconductor substrate 100 to define an active area. Although not shown, a well area may be formed in the semiconductor substrate 100 through an ion implantation process.

As shown in FIG. 1, after sequentially depositing a first oxide layer 111a, a first polysilicon layer 112a, a second oxide layer 113a, and a first nitride layer 114a, a first photoresist pattern 200 is formed on the first nitride layer 114a.

The first oxide layer 111a may be formed through one of a thermal process, a chemical vapor deposition (CVD) process and an atomic layer deposition (ALD) process.

The first polysilicon layer 112a may be formed on the first oxide layer 111a through a low pressure chemical vapor deposition (LPCVD) process.

The second oxide layer 113a and the first nitride layer 114a may be formed through CVD processes.

The first photoresist pattern 200 on the first nitride layer 114a defines a region where a pair of first polysilicon floating gate patterns 112 will be formed.

As shown in FIG. 2, the first oxide layer 111a, the first polysilicon layer 112a, the second oxide layer 113a, and the first nitride layer 114a are etched by using the first photoresist pattern 200 as a mask.

Through the etch process, a first oxide layer pattern 111, a first polysilicon pattern 112b, a second oxide layer pattern 113, and a first nitride layer pattern 114 are formed on the semiconductor substrate 100.

The first oxide layer pattern 111 performs a tunnel oxide function.

The first polysilicon pattern 112b is further patterned in a subsequent process to serve as a floating gate.

The second oxide layer pattern 113 performs a buffer oxide function to protect the first polysilicon pattern 112b during subsequent etching processes.

The first nitride layer pattern 114 defines an area for a self-aligned control gate formed thereafter.

Next, as shown in FIG. 3, a third oxide layer 110 is formed. The third oxide layer 110 can be formed on sidewalls of the first polysilicon pattern 112b and on the semiconductor substrate 100. The third oxide layer 110 may not be formed on the first nitride layer pattern 114. After the third oxide layer 110 has been deposited, a second polysilicon layer 116a is deposited on the semiconductor substrate 100 at the height equal to or greater than the height of the stacked patterns 111, 112b, 113, and 114 while covering the stacked patterns 111, 112b, 113, and 114.

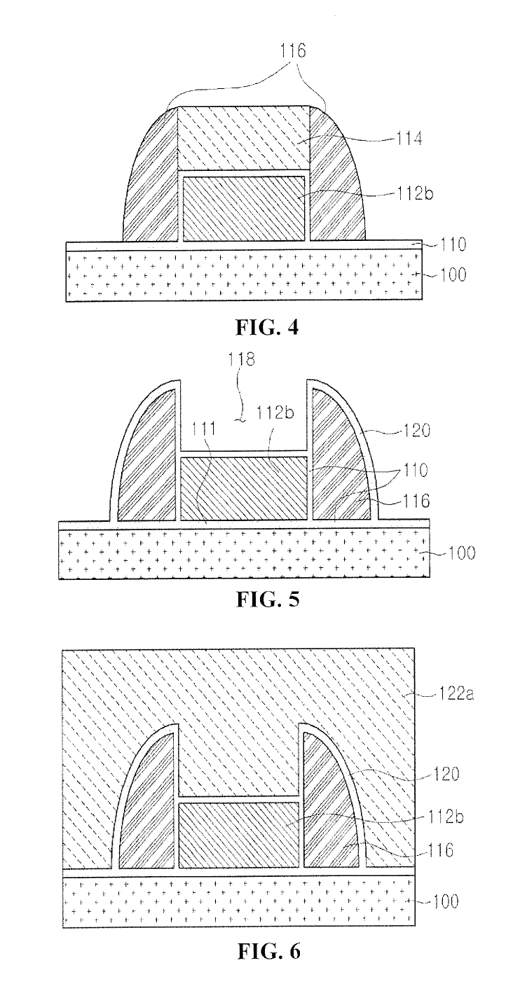

As shown in FIG. 4, the second polysilicon layer 116a is etched to form a second polysilicon pattern 116 having the form of a spacer while making contact with the lateral sides of the stacked patterns 111, 112b, 113, and 114. The second polysilicon layer 116a may be etched through a dry etch-back scheme.

The second polysilicon pattern 116 has the same height as that of the stacked patterns 111, 112b, 113, and 114 on the semiconductor substrate 100, and exposes only a top surface of the first nitride layer pattern 114 positioned at the uppermost layer of the stacked patterns 111, 112b, 113, and 114.

Next, as shown in FIG. 5, the first nitride layer pattern 114 is removed to expose the second oxide layer pattern 113 at a top surface of the first polysilicon pattern 112b and inner lateral sides of the second polysilicon pattern 116 having the form of spacers protruding from the lateral sides of the first polysilicon pattern 112b. Therefore, a control gate area 118 restricted by the first polysilicon pattern 112b and the second polysilicon pattern 116 is formed.

A fourth oxide layer 120 is deposited on the exposed surfaces of the second polysilicon pattern 116. The fourth oxide layer 120 performs a buffer oxide function.

Accordingly, the first oxide layer pattern 111 is interposed between the first polysilicon pattern 112b remaining on the semiconductor substrate 100 and the semiconductor substrate 100. The third oxide layer 110 is interposed between the second polysilicon pattern 116 and the semiconductor substrate 100, and between the first polysilicon pattern 112b and the second polysilicon pattern 116. The second oxide layer pattern 113 may remain on the first polysilicon pattern 112b. The fourth oxide layer 120 is formed on the exposed surface of the second polysilicon pattern 116.

Next, as shown in FIG. 6, a second nitride layer 122a is deposited to cover the semiconductor substrate 100 including the first polysilicon pattern 112b and the second polysilicon pattern 116.

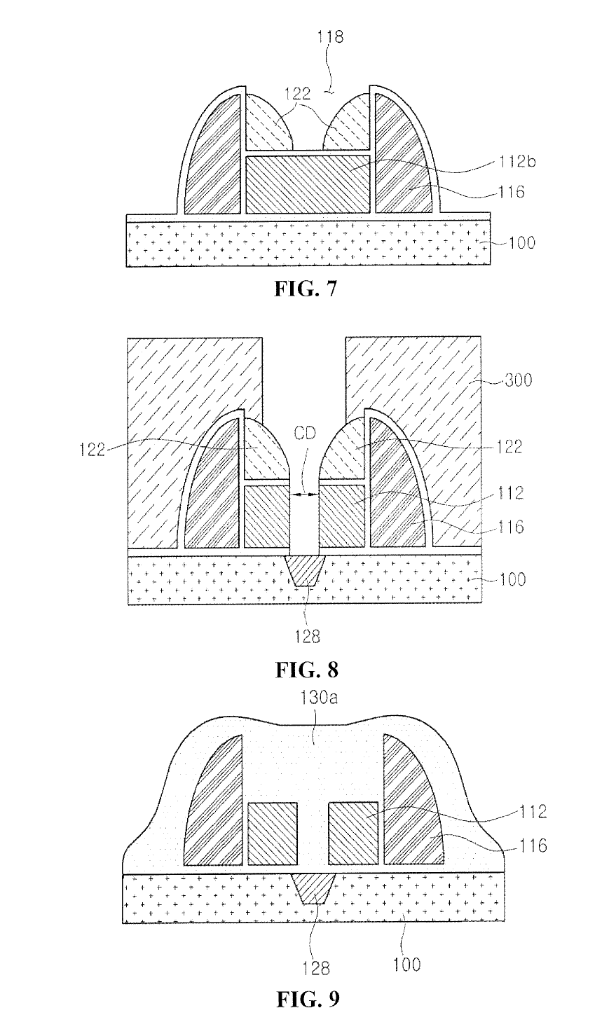

As shown in FIG. 7, the second nitride layer 122a is etched to form a pair of hard mask patterns 122 having the form of a spacer within the control gate area 118 such that a central portion of the control gate area 118 is exposed. The second nitride layer 122a may be etched through an etch-back scheme.

The hard mask patterns 122 have the form of a pair of spacers making contact with the third layer pattern 113 on the top surface of the first polysilicon pattern 112b and the fourth oxide layer 120 on the interior sidewalls of the second polysilicon pattern 116 in the control gate area 118, thereby exposing a region corresponding to a central portion of the first polysilicon pattern 112b by a critical dimension (CD) between the first polysilicon floating gate patterns 112 (see FIG. 8) formed in the subsequent process.

The hard mask patterns 122 formed using the second nitride layer 122a ensures a margin when the first polysilicon floating gate patterns 112 are formed through a photolithography process for the etching of the first polysilicon pattern 112b. When the first polysilicon pattern 112b is etched, the hard mask pattern 122 blocks miss overlay to maintain the CD between the first polysilicon floating gate patterns 112 (see FIG. 8). Accordingly, the reliability of the photolithography process can be improved, and a uniform structure and uniform characteristics can be ensured between neighboring cells.

After the hard mask patterns 122 have been formed, a second photoresist pattern 300 is formed to define a floating gate area in the first polysilicon pattern 112b as shown in FIG. 8.

When an etch process is performed using the second photoresist pattern 300 as a mask, a central portion of the first polysilicon pattern 112b and the first oxide layer 111 corresponding to the central portion are removed to expose the semiconductor substrate 100. The first polysilicon pattern 112b is patterned to form the neighboring first polysilicon floating gate patterns 112. The CD between the first polysilicon floating gate patterns 112 must be set as small as possible such that a gap-filled top surface is planarized when the space between the first polysilicon floating gate patterns 112 is gap-filled in the subsequent process.

After the first polysilicon floating gate patterns 112 have been formed, impurities are implanted into the exposed portion of the semiconductor substrate 100 to form a source junction 128.

As shown in FIG. 9, the hard mask patterns 122 are removed, and a fifth oxide layer 130a is deposited such that the fifth oxide layer 130a is gap-filled in the space between the first polysilicon floating gate patterns 112.

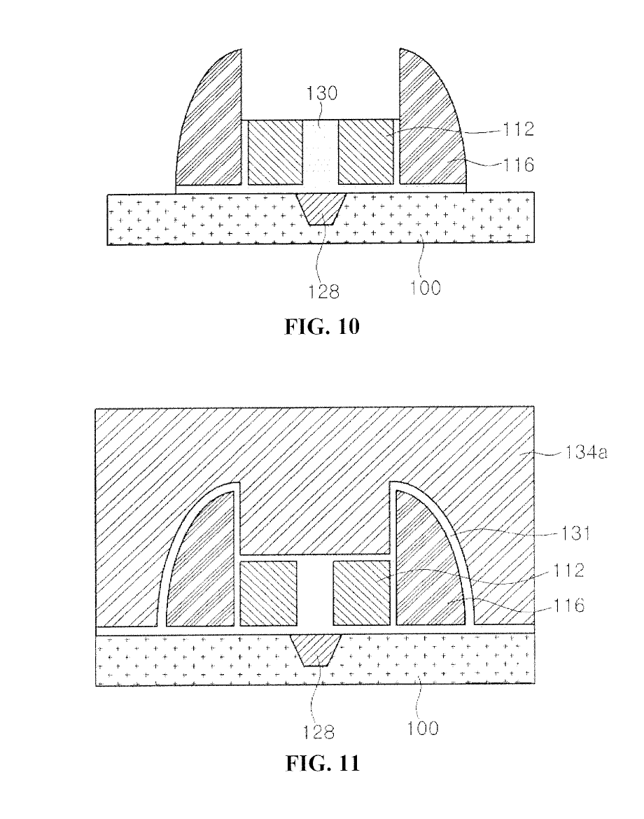

As shown in FIG. 10, the fifth oxide layer 130a is removed through a wet etch-back such that a fifth oxide layer pattern 130 remains gap-filled in the space between the first polysilicon floating gate patterns 112. The fifth oxide layer pattern 130 has a height equal to that of the first polysilicon floating gate pattern 112. The fifth oxide layer pattern 130 inhibits a third polysilicon layer 134a (see FIG. 11) from being deposited in the space between the first polysilicon floating gate patterns 112 in the subsequent process.

After the fifth oxide layer 130a has been removed through the wet etch-back scheme, the surface of the substrate 100, the second polysilicon pattern 116, and the first polysilicon floating gate patterns 112 are exposed.

As shown in FIG. 11, after deposing a sixth oxide layer 131 on the exposed surfaces, a third polysilicon layer 134a is deposited.

The sixth oxide layer 131 compensates for a lost oxide layer when the fifth oxide layer 130a is subject to an etch-back process. The sixth oxide layer 131 serves as a gate oxide layer for the third polysilicon layer 134a. In a dry etch-back process, the sixth oxide layer 131 may also be used as a buffer layer of the second polysilicon pattern 116.

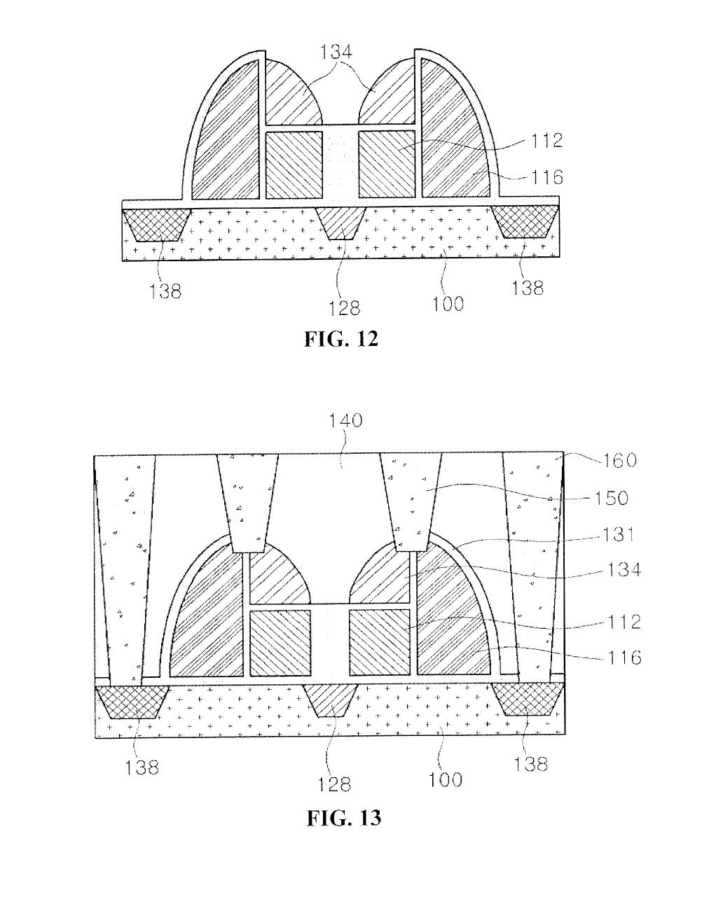

As shown in FIG. 12, the third polysilicon layer 134a is etched to form third polysilicon patterns 134 that have the form of spacers and are positioned on top surfaces of the first polysilicon floating gate patterns 112, while making contact with the sixth oxide layer 131 at sidewalls of the second polysilicon pattern 116.

The third polysilicon patterns 134 may be formed by performing a dry etch-back scheme with respect to the third polysilicon layer 134a and by using the second polysilicon pattern 116 as a fence layer and the sixth oxide layer 131 as a buffer layer of the second polysilicon pattern 116.

The third polysilicon pattern 134 having the form of a spacer has a bottom surface that is positioned on the top surface of the first polysilicon floating gate pattern 112 while contacting the sixth oxide layer 131, and sidewalls making contact with the sixth oxide layer 131 at the sidewalls of the second polysilicon pattern 116. In addition, the third polysilicon pattern 134 has a height substantially identical to that of the second polysilicon pattern 116.

After the third polysilicon pattern 134 has been formed, impurities are implanted into the semiconductor substrate 100 to form a drain junction 138.

Next, as shown in FIG. 13, interlayer dielectrics (ILD) 140 are formed. Then, a first contact 150 simultaneously shorting the second polysilicon pattern 116 and the third polysilicon pattern 134, and a second contact 160 connected with the drain junction 138 are formed.

The first contact 150 makes contact with the second polysilicon pattern 116, the sixth oxide layer 131, and the third polysilicon pattern 134. Accordingly, the first contact 150 allows the second polysilicon pattern 116 and the third polysilicon pattern 134 to serve as one control gate by simultaneously shorting the second polysilicon pattern 116 and the third polysilicon pattern 134.

Accordingly, a lateral side of the first polysilicon floating gate pattern 112 corresponds to (and is controlled by) the second polysilicon pattern 116, and the top surface of the first polysilicon floating gate pattern 112 corresponds to (and is controlled by) the third polysilicon pattern 134, such that a contact area between the floating gate and the control gate is increased. Accordingly, a coupling rate is increased.

If a voltage is applied to the second polysilicon pattern 116 and the third polysilicon pattern 134 through the first contact 150 in the above structure, a voltage is applied to the first polysilicon floating gate pattern 112. Accordingly, channel hot electrons are generated in the drain junction 138 and stored in a floating gate (the first polysilicon floating gate pattern 112). As described above, program/erase operations can be controlled by applying a voltage to the second polysilicon pattern 116 and the third polysilicon pattern 134.

As described above, in the semiconductor device according to an embodiment, a self-aligned gate process is performed by using a nitride layer as a hard mask, so that a uniform structure and a uniform characteristic can be maintained between adjacent cells.

The second polysilicon pattern 116 and the third polysilicon pattern 134, respectively formed on the lateral side and the top surface of the first polysilicon floating gate pattern 112, are used as a control gate. Accordingly, the contact area between the floating gate and the control gate is increased, so that a coupling rate characteristic can be improved. Therefore, more effective lower-power driving can be realized.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a first polysilicon pattern formed on a semiconductor substrate;
a second polysilicon pattern formed at a lateral side of the first polysilicon pattern, wherein the second polysilicon pattern has a height higher than that of the first polysilicon pattern;
a third polysilicon pattern formed in a region restricted by a top surface of the first polysilicon pattern and a lateral side of the second polysilicon pattern; and
a contact electrically connecting the second polysilicon pattern and the third polysilicon pattern.

2. The semiconductor device of claim 1, further comprising:
a tunnel oxide layer interposed between the first polysilicon pattern and the semiconductor substrate;
a first gate oxide layer interposed between the second polysilicon pattern and the semiconductor substrate; and
a second gate oxide layer on the first polysilicon pattern and the lateral side of the second polysilicon pattern such that the second gate oxide layer is interposed between the top surface of the first polysilicon pattern and the third polysilicon pattern and interposed between the lateral side of the second polysilicon pattern and the third silicon pattern and interposed between the lateral side of the second polysilicon pattern and the first polysilicon pattern.

3. The semiconductor device of claim 1, further comprising:
a first impurity region formed on the semiconductor substrate at one side of the first polysilicon pattern; and
a second impurity region formed on the semiconductor substrate at one side of the second polysilicon pattern.

4. A method of manufacturing a semiconductor device, the method comprising:
forming a stack of a first oxide layer pattern, a first polysilicon pattern, a second oxide layer pattern, and a first nitride layer pattern on a semiconductor substrate;
forming a second polysilicon pattern having a form of a spacer while making contact with lateral sides of the first oxide layer pattern, first polysilicon pattern, second oxide layer pattern, and first nitride layer pattern stack on the semiconductor substrate;
removing the first nitride layer pattern from between the second polysilicon pattern contacting the lateral sides of the first nitride layer pattern to form a control gate area;
forming a pair of hard mask patterns having the form of a spacer in the control gate area, wherein the pair of hard mask patterns is formed on a top surface of the first polysilicon pattern and respective inner sidewalls of the second polysilicon pattern;
forming first polysilicon floating gate patterns adjacent to each other by etching the first polysilicon pattern using the hard mask patterns as an etch mask until the semiconductor substrate is exposed at a central portion of the first polysilicon pattern;
gap-filling a space between the first polysilicon floating gate patterns;
forming a third polysilicon pattern in a region restricted by a top surface of the first polysilicon floating gate patterns and a lateral side of the second polysilicon pattern; and
forming a contact electrically connected with the second polysilicon pattern and the third polysilicon pattern.

5. The method of claim 4, wherein the forming of the second polysilicon pattern having the form of the spacer comprises:
depositing a buffer oxide layer at the lateral sides of the first oxide layer pattern, the first polysilicon pattern, the second oxide layer pattern, and the first nitride layer pattern stacked on the semiconductor substrate;
depositing a second polysilicon layer on the buffer oxide layer; and
performing a dry etch-back process with respect to the second polysilicon layer.

6. The method of claim 5, further comprising depositing a buffer oxide layer on an exposed surface of the second polysilicon pattern.

7. The method of claim 4, wherein the forming of the pair of hard mask patterns comprises:
depositing a second nitride layer to cover the semiconductor substrate including the first polysilicon pattern and the second polysilicon pattern; and
performing an etch-back process with respect to the second nitride layer.

8. The method of claim 4, wherein the forming of the third polysilicon pattern in the region restricted by the top surface of the first polysilicon floating gate patterns and the lateral side of the second polysilicon pattern comprises:
depositing a gate oxide layer on the top surface of the first polysilicon floating gate patterns and the lateral sides of the second polysilicon pattern;
forming a third polysilicon layer to cover the top surface of the first polysilicon floating gate patterns and the lateral sides of the second polysilicon pattern; and
performing a dry etch-back process to form the third polysilicon pattern using the second polysilicon pattern as a fence layer.

9. The method of claim 4, further comprising forming a first impurity region on the semiconductor substrate exposed at the central portion of the first polysilicon pattern.

10. The method of claim 4, further comprising forming a second impurity region on the semiconductor substrate at one side of the second polysilicon pattern.
